(19) United States
(12) Patent Application Publication
(10) Pub. No.: US 2026/0018429 A1
(43) Pub. Date: Jan. 15, 2026

(54) MIXED GAS SUPPLY DEVICE

(71) Applicant: TAIYO NIPPON SANSO CORPORATION, Tokyo (JP)

(72) Inventors: Hayato MURATA, Tokyo (JP); Daisuke SONE, Tokyo (JP); Ryo SUGIURA, Tokyo (JP); Yasuhito KODA, Tokyo (JP); Kenichi IMAI, Tokyo (JP)

(21) Appl. No.: 18/995,016

(22) PCT Filed: Aug. 10, 2023
(86) PCT No.: PCT/JP2023/029286

§ 371 Date: Jan. 15, 2025

(30) Foreign Application Priority Data
Aug. 17, 2022 (JP) 2022-130120

(51) Int. Cl. H01L 21/67

(52) U.S. Cl. CPC H01L 21/67017

(57) ABSTRACT

The present invention addresses the problem of providing a mixed gas supply device that can safely and stably supply a mixed gas containing a film forming material gas. The present invention provides a mixed gas supply device that supplies a mixed gas containing at least one kind of gas of a film forming material by adjusting the concentration of the film forming material in the mixed gas, comprising: a raw material container (2) that contains the film forming material; a first beater (3) that heats the raw material container (2); a carrier gas-introduction path (L1) that introduces a carrier gas into the raw material container (2); a mixed gas-lead-out path (L2) that leads the mixed gas out of the raw material container (2); a second heater (6) that heats the mixed gas lead-out path (L2); a pressure adjusting device (8) that is located in the mixed gas lead-out path (L2) and that adjusts the pressure in the raw material container (2); a mixed gas-measuring device (9) that is located in the mixed gas lead-out path (L2) on the primary or secondary side of the pressure adjusting device (8) and that measures the concentration or the flow rate of the mixed gas; and one or more buffer tanks (10) that are located in the mixed gas lead-out path (12).

### TECHNICAL FIELD

The present invention relates to a mixed gas supply device.

### BACKGROUND ART

In semiconductor manufacturing processes, metal thin films, metal oxide films, and metal nitride films are used in many processes. For example, metal nitride films are widely used for many applications due to their physical, chemical, electrical, and mechanical properties. Silicon nitride films (SiN) are used as gate insulating films and sidewall spacers, and the like when forming transistors. Titanium nitride films (TiN), tantalum nitride films (TaN), and tungsten nitride films (WN) are used as barrier films for wiring in integrated circuits.

In recent years in particular, there has been a great advancement in miniaturization of three-dimensional transistor structures such as Fin-FETs (Fin Field-Effect Transistors) in advanced logic, as well as in the high integration of 3D-NAND. As the horizontal and vertical dimensions of integrated circuits continue to be small, there is a demand for thin-film formation technologies that can control film thickness on the sub-nanometer order and have good coverage characteristics.

In general, in order to form a thin film by chemical vapor deposition (CVD) or atomic layer deposition (ALD), a film forming material such as a metal containing compound, a nitrogen containing compound, an oxide containing compound, or a carbon containing compound must be gasified and supplied. However, since the film forming material often has a low vapor pressure, it must be vaporized before being supplied to a film forming reactor.

As a method for supplying a film forming material to a film forming reactor, Patent Documents 1 and 2 disclose a technology for supplying a mixed gas of vapor of the film forming material (film forming material gas) and a carrier gas by aerating and bubbling the inside of a raw material container with the carrier gas. In the case of bubbling supply, the temperature of the film forming material and the pressure inside the raw material container are kept constant, and the flow rate of the carrier gas is controlled, so that the mixed gas of the film forming material gas and the carrier gas can be supplied at a stable concentration.

Patent Document 3 also discloses a technology in which a pipe (dip tube) immersed in the liquid material filled in a container and a pressurizing gas pipe are installed, the liquid level in the container is pressurized by introducing a pressurizing gas into the pressurizing gas pipe, and the liquid material is supplied to a consuming facility through the dip tube. In the case of Patent Document 3, after the liquid material is generally supplied, and vaporized by a vaporizer or the like, so that the liquid material can be supplied to a film formation reactor at a stable flow rate.

### PRIOR ART DOCUMENTS

### Patent Documents

Patent Document 1 Japanese Unexamined Patent Application, First Publication No. 2005-522869
Patent Document 2 Japanese Unexamined Patent Application, First Publication No. 2015-119045
Patent Document 3 Japanese Unexamined Patent Application, First Publication No. 2011-025104

### SUMMARY OF INVENTION

### Problem to be Solved by the Invention

In the techniques disclosed in Patent Documents 1 and 2, even if the temperature of the film forming material and the pressure in the raw material container are kept constant and the flow rate of the carrier gas is controlled, the concentration of the film forming material gas fluctuates immediately after the supply of the mixed gas, and the concentration is not uniform (the set concentration is not reached). In addition, during the supply of the mixed gas, a decrease in the vapor pressure of the film forming material (a decrease in the film forming material temperature) occurs in the raw material container due to the heat of vaporization, and the concentration of the film forming material gas in the mixed gas decreases (fluctuations).

The change in the concentration of the film forming material gas in the mixed gas due to the change in vapor pressure can be suppressed by controlling the pressure in the raw material container. However, changing the pressure in the raw material container may cause the flow rate of the mixed gas to change, which may cause the supply amount (absolute amount) of the film forming material gas to change.

In addition, the technology disclosed in Patent Document 3 has the advantage that the concentration of the mixed gas can be kept constant because the flow rate of the mixed gas can be controlled by the vaporizer. However, there is a risk of liquid material leaking from the joints of the pipes. If the liquid material is water-repellent, highly reactive, toxic, and the like, even if it is a small amount, there is a safety issue.

The present invention has been made in view of the above circumstances, and an object of the present invention is to provide a mixed gas supply device that can safely and stably supply a mixed gas containing a film forming material gas.

### Means for Solving the Problem

In order to solve the above problems, the present invention has the following configurations.

[1] A mixed gas supply device that supplies a mixed gas containing at least one kind of gas of a film forming material by adjusting the concentration of the film forming material in the mixed gas, including:

a raw material container that contains the film forming material;
a first heater that heats the raw material container;
a carrier gas-introduction path that introduces a carrier gas into the raw material container;

a mixed gas-lead-out path that leads the mixed gas out of the raw material container;

a second heater that heats the mixed gas lead-out path;

a pressure adjusting device that is located in the mixed gas lead-out path and that adjusts the pressure in the raw material container;

a mixed gas-measuring device that is located in the mixed gas lead-out path on the primary or secondary side of the pressure adjusting device and that measures the concentration or the flow rate of the mixed gas; and
one or more buffer tanks that are located in the mixed gas lead-out path.

[2] The mixed gas supply device according to [1],
wherein the buffer tank includes a first buffer tank that is located on the secondary side of the mixed gas-measuring device.

10 [3] The mixed gas supply device according to [1] or [2],
wherein the mixed gas supply device further includes a mixed gas-concentration adjusting device that adjusts a concentration of the film forming material in the mixed gas to a set value, and
wherein the mixed gas-concentration adjusting device has a function of calculating a difference between a measured value of the concentration of the mixed gas obtained by the mixed gas-measuring device and the set value set in the mixed gas-concentration adjusting device, and updating a set pressure value of the pressure adjusting device based on the difference so that the measured value becomes the set value.

[4] The mixed gas supply device according to [1] or [2],
wherein the mixed gas supply device further includes:
a mixed gas-concentration adjusting device that adjusts the concentration of the film forming material in the mixed gas to a set value;

a carrier gas-flow rate control device that is located in the carrier gas-introduction path; and
a mixed gas-concentration calculation device that calculates a concentration of the film forming material in the mixed gas based on a set value of the flow rate of the carrier gas set in the carrier gas-flow rate control device and a measured value of the flow rate of the mixed gas measured by the mixed gas-measuring device, and
wherein the mixed gas-concentration adjusting device has a function of calculating a difference between a calculated value of the concentration of the mixed gas obtained by the mixed gas-concentration calculation device and the set value set in the mixed gas-concentration adjusting device, and updating a set pressure value of the pressure adjusting device based on the difference so that the calculated value becomes the set value.

[5] The mixed gas supply device according to any one of [1] to [4],
wherein the buffer tank includes a second buffer tank that is located between the pressure adjusting device and the mixed gas-measuring device.

[6] The mixed gas supply device according to any one of [1] to [5],
wherein the mixed gas supply device further includes:
a first heater adjusting device that adjusts an output of the first heater;

a mixed gas-concentration adjusting device that adjusts a concentration of the film forming material in the mixed gas to a set value;

a carrier gas-flow rate control device that is located in the carrier gas-introduction path; and
a mixed gas-concentration calculation device that calculates a concentration of the film forming material in the mixed gas based on a set value of the flow rate of the carrier gas set in the carrier gas-flow rate control device and a measured value of a flow rate of the mixed gas measured by the mixed gas-measuring device, and
wherein the mixed gas-concentration adjusting device has a function of calculating a difference between a measured value of a concentration of the mixed gas obtained by the mixed gas-measuring device or a calculated value of a concentration of the mixed gas obtained by the mixed gas-concentration calculation device and the set value set in the mixed gas-concentration adjusting device, and updating a set value of an output of the first heater adjusting device so that the measured value or the calculated value becomes the set value based on the difference.

[7] The mixed gas supply device according to any one of [2] to [6],
wherein the mixed gas supply device further includes:
a carrier gas-flow rate control device that is located in the carrier gas-introduction path,
a pressure measuring device that measures the pressure in the first buffer tank, and
a supply control device that controls the carrier gas-flow rate control device and one or more on-off valves located in the mixed gas lead-out path, and
wherein the supply control device controls the carrier gas-flow rate control device and each of the opening degrees of the one or more on-off valves based on the measurement value of the pressure measuring device.

[8] The mixed gas supply device according to any one of [2] to [7],
wherein the mixed gas supply device further includes:
a mixed gas-flow rate control device that is located in the mixed gas lead-out path on the secondary side of the first buffer tank.

[9] The mixed gas supply device according to [7],
wherein the mixed gas supply device further includes:
a mixed gas-flow rate control device that is located in the mixed gas lead-out path on the secondary side of the first buffer tank.

The mixed gas supply device according to any one of [1] to [9],
wherein the film forming material is one or more compounds selected from the group consisting of a metal containing compound, a nitrogen containing compound, a carbon containing compound, and an oxygen containing compound.

The mixed gas supply device according to [10],
wherein the nitrogen containing compound is a hydrazine compound.

The mixed gas supply device according to any one of [1] to [11],
wherein the mixed gas supply device further includes a bypass path that is branched off from the carrier gas-introduction path, bypasses the raw material container and merged with the mixed gas lead-out path.

[13] The mixed gas supply device according to any one of [1] to [12],
wherein the mixed gas supply device further includes one or more exhaust paths that are branched off from the mixed gas lead-out path, and exhaust the mixed gas in the mixed gas lead-out path.

### Effects of the Invention

The mixed gas supply device of the present invention can safely and stably supply a mixed gas containing a film forming material gas.

### BRIEF DESCRIPTION OF THE DRAWINGS

FIG. 1 is a system diagram showing the configuration of a first embodiment of a mixed gas supply device of the present invention.

FIG. 2 is a system diagram showing the configuration of a second embodiment of a mixed gas supply device of the present invention.

FIG. 3 is a system diagram showing the configuration of a third embodiment of a mixed gas supply device of the present invention.

FIG. 4 is a system diagram showing the configuration of a fourth embodiment of a mixed gas supply device of the present invention.

FIG. 5 is a system diagram showing the configuration of a fifth embodiment of a mixed gas supply device of the present invention.

FIG. 6 is a system diagram showing the configuration of a sixth embodiment of a mixed gas supply device of the present invention.

FIG. 7 is a diagram showing the results of Example 1 of the present invention.

FIG. 8 is a diagram showing the results of Comparative Example 1 of the present invention.

FIG. 9 is a diagram showing the results of Example 2 of the present invention.

FIG. 10 is a diagram showing the results of Example 2 of the present invention.

FIG. 11 is a diagram showing the results of Example 3 of the present invention.

FIG. 12 is a diagram showing the results of Example 4 of the present invention.

FIG. 13 is a diagram showing the results of Comparative Example 2 of the present invention.

### DETAILED DESCRIPTION OF THE PREFERRED EMBODIMENTS

Hereinafter, a mixed gas supply device, which is an embodiment according to the present invention, will be described in detail with reference to the drawings. Note that the figures used in the following description may show characteristic parts in an enlarged scale for the sake of convenience in order to make the characteristics easier to understand, and the dimensional ratios of each component may not necessarily be the same as the actual ones.

Furthermore, “˜” indicating a range of values means that the values before and after it are included as the lower and upper limits.

### First embodiment

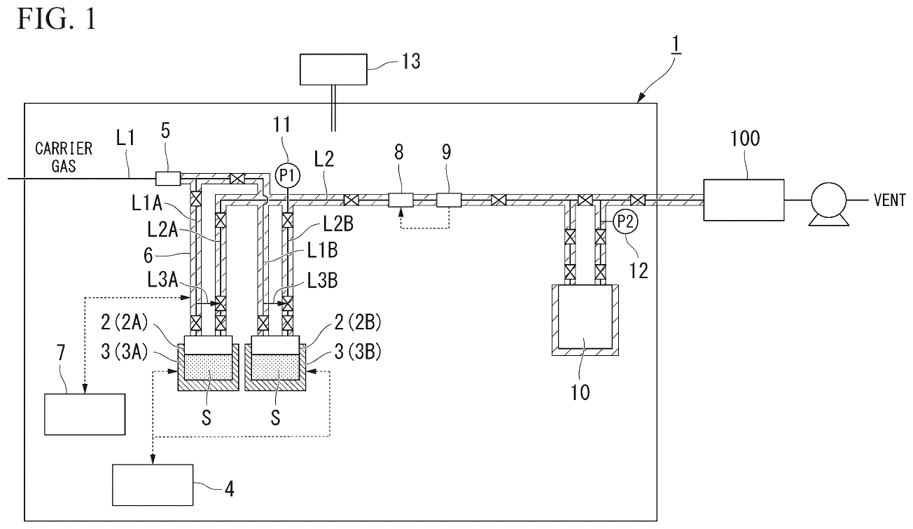

A first embodiment of the mixed gas supply device of the present invention will be described in detail with reference to the drawings. FIG. 1 is a system diagram showing the configuration of a first embodiment of the mixed gas supply device.

As shown in FIG. 1, the mixed gas supply device 1 of the present embodiment includes a raw material container 2 (2A, 2B), a container heater (first heater) 3 (3A, 3B), a pipe heater (second heater) 6, a pressure adjusting device 8, a mixed gas-measuring device 9, a first buffer tank (buffer tank) 10, a first pressure measuring device 11, a second pressure measuring device (pressure gauge) 12, a detector 13, a carrier gas-introduction path L1 (L1A, L1B), a mixed gas-lead-out path L2 (L2A, L2B), and a bypass path L3 (L3A, L3B).

The mixed gas supply device 1 of the present embodiment may further include a container heater-temperature adjusting device (first heater adjusting device) 4, a carrier gas-flow rate control device 5, and a pipe heater-temperature adjusting device (second heater adjusting device) 7.

The mixed gas supply device 1 of the present embodiment is a device that adjusts the concentration of a mixed gas containing at least one kind of a gas of a film forming material, and supplies the mixed gas to, for example, a downstream film forming apparatus 100.

There are no particular limitations on the film forming apparatus 100 as long as it is applicable to a chemical vapor deposition method. Examples of the film forming apparatus 100 include a chemical vapor deposition (CVD) apparatus and an atomic layer deposition (ALD) apparatus,

The raw material container 2 (2A, 2B) is a container (supply source) that contains a film forming material S inside.

The number of raw material containers 2 may be one, or two or more. Below, in the mixed gas supply device 1 of the present embodiment, a case, in which two raw material containers 2A, 2B are used, will be described as an example.

In the mixed gas supply device 1 of the present embodiment, the two raw material containers 2A and 2B may be used one by one, or two may be used simultaneously. When the two raw material containers 2A and 2B are used one by one, the film forming material S can be continuously supplied by switching to the other container after one container becomes empty. In addition, when the two raw material containers 2A and 2B are used simultaneously, the contact area between the carrier gas and the film forming material increases, so that the concentration of the gas of the film forming material in the mixed gas can be increased. Note that, as for the mode of use of the raw material container 2, an appropriate method can be appropriately selected according to the film forming process in the film forming apparatus 100.

The film forming material S is a material that is liquid or solid at room temperature and pressure, and is used in thin film formation processes such as CVD and ALD. The film forming material S is one or more compounds selected from the group consisting of metal containing compounds, nitrogen containing compounds, carbon containing compounds, and oxygen containing compounds.

### Metal Containing Compound

The metal containing compound is not particularly limited, but may include one or more metal elements selected from the group consisting of silicon (Si), titanium (Ti), tantalum (Ta), aluminum (Al), gallium (Ga), vanadium (V), iron (Fe), zirconium (Zr), niobium (Nb), tungsten (W), molybdenum (Mo), indium (In), hafnium (Hf), cobalt (Co), and ruthenium (Ru).

Among the metal containing compounds, halogen metal compounds are preferably selected from TiCl₄, Si₂Cl (HCDS: hexachlorodisilane) , SiCl₄, SiHCl₃, SiH₂Cl₂, SiH₃Cl, SiI₄, SiHI₃, SiH₂I₂, SiH₃I, TaCl₅, AlCl₃, GaCl₃, ZrCl₄, HfCl₄, MoO₂Cl₅, MoCl₅, WF₆, WCl₆, and WCl₅.

Among the metal containing compounds, organometallic compounds are preferably selected from TDMAT (tetrakisdimethylaminotitanium), 3DMAS (trisdimethylaminosilane), BDEAS (bisdiethylaminosilane), BTBAS (bistertiarybutylaminosilane), DIPAS (diisopropylaminosilane), PDMAT (pentakisdimethylaminotantalum), TMA (trimethylaluminum), TMG (trimethylgallium), hafnium containing compounds, zirconium containing compounds, cobalt containing compounds, and ruthenium containing compounds. (Nitrogen containing compounds)

The nitrogen containing compounds are not particularly limited, but examples thereof include amine compounds, hydrazine compounds, and ammonia.

The amine compound is preferably a compound selected from the group consisting of methylamine, dimethylamine, ethylamine, diethylamine, and tertiary butylamine.

The hydrazine compound is not particularly limited, but examples thereof include hydrazine (N₂H₄), monomethylhydrazine, dimethylhydrazine, tertiary butylhydrazine, phenylhydrazine, propylhydrazine. As the hydrazine compound, any one selected from the group may be used, or two or more kinds may be mixed and used.

Generally, hydrazine compounds are known to cause explosive reactions, as used as propellants for spacecraft and fuels for rocket engines. In addition, hydrazine and monomethylhydrazine are highly toxic, with a tolerance concentration (TLV-TWA) of 0.01 ppm, which is significantly lower than the tolerance concentration of ammonia (tolerable concentration: 25 ppm), phosphine (tolerable concentration: 0.3 ppm), and monosilane (tolerable concentration: 5 ppm) used in semiconductor manufacturing processes. These properties are also evident from the fact that hydrazine is rated 4-4-3 (Health-Flammability-Instability) and monomethylhydrazine is rated 4-3-2 in the National Fire Protection Association (NFPA), a standard indicating the hazards of chemicals, and sufficient consideration must be given to safety when handling them. For this reason, it is preferable that the raw material container 2 be a sealed container.

### Carbon Containing Compounds

Examples of carbon containing compounds include, but are not limited to, organic solvents. As the organic solvent, one or more compounds selected from the group consisting of hydrocarbon compounds, alcohol compounds, ether compounds, glycol compounds, and ketone compounds can be used.

### Oxygen Containing Compounds

Examples of oxygen containing compounds include, but are not limited to, water (H₂O) and hydrogen peroxide (H₂O₂).

It should be noted that the film forming material S may be a mixture of two or more kinds of liquid, or a solid dissolved in a liquid.

Furthermore, the term “gas of film forming material” refers to a film forming material in a gasified state.

The container heaters 3 (3A, 3B) are positioned around the raw material containers 2 (2A, 2B) and heat the raw material containers 2 (2A, 2B) so that the film forming material S in the raw material containers 2 (2A, 2B) is within a predetermined temperature range.

The container heaters 3 (3A, 3B) are not particularly limited as long as they can heat the raw material containers 2 (2A, 2B). Examples of the container heaters 3 (3A, 3B) include breeze heaters, mantle heaters, water baths, and oil baths. Among these, it is preferable to use a water bath or oil bath when heating the film forming material S in the containers from the standpoint of thermal uniformity and safety.

There are no particular limitations on the container heater-temperature adjusting device 4 as long as it can regulate (control) the output of the container heater 3 (3A, 3B). Note that the container heater-temperature adjusting device 4 only needs to have a function of regulating (controlling) the output of the container heater 3 (3A, 3B), and may be integrated with the container heater 3 (3A, 3B).

The temperature to which the raw material container 2 (2A, 2B) is heated by the container heater 3 (3A, 3B) and the container heater-temperature adjusting device 4 is preferably set to a temperature at which the film forming material S does not decompose, from the viewpoint of safety and stable supply of the film forming material S. Specifically, the temperature is preferably set in the range of room temperature (20° C.) to 200° C., and more preferably in the range of 30° C. to 60° C.

The carrier gas-introduction path L1 is a flow path that introduces a carrier gas into the raw material container 2. A base end of the carrier gas-introduction path L1 is connected to a carrier gas supply source (not shown). A tip end of the carrier gas-introduction path L1 in the gas flow direction is connected to the raw material container 2. In the present embodiment, the tip end of the carrier gas-introduction path L1 branches into a path L1A and a path L1B, and the path L1A is connected to the raw material container 2A, and the path L1B is connected to the raw material container 2B. As a result, according to the mixed gas supply device 1 of the present embodiment, the carrier gas can be introduced into each of the raw material containers 2A and 2B through the carrier gas-introduction path L1.

The carrier gas is not particularly limited, and can be appropriately selected depending on the kind of the film forming material S. Examples of the carrier gas include rare gases such as helium (He), nitrogen (N2), and argon (Ar), hydrogen (H₂), and ammonia (NH₃). As the carrier gas, one of these may be selected and used, or two or more may be mixed and used.

The carrier gas-flow rate control device 5 is located in the carrier gas-introduction path L1. The carrier gas-flow rate control device 5 controls the flow rate of the carrier gas supplied to the carrier gas-introduction path L1. The carrier gas-flow rate control device 5 is not particularly limited as long as it can control the flow rate. Examples of the carrier gas-flow rate control device 5 include a mass flow rate controller (MFC) and a pressure adjusting device that can control the opening degree.

The flow rate of the carrier gas supplied to the carrier gas-introduction path L1 is not particularly limited and can be appropriately selected. The control range of the flow rate of the carrier gas by the carrier gas-flow rate control device 5 is preferably in the range of 10 to 10,000 sccm.

The mixed gas-lead-out path L2 is a flow path that leads out a mixed gas containing at least one or more kinds of gas of the film forming material S from the raw material container 2. The base end of the mixed gas-lead-out path L2 is connected to the raw material container 2. In the present embodiment, the base end of the mixed gas-lead-out path L2 branches into a path L2A and a path L2B, and the path L2A is connected to the raw material container 2A, and the path L2B is connected to the raw material container 2B. In addition, the tip of the mixed gas-lead-out path L2 is connected to the film forming apparatus 100. As a result, according to the mixed gas supply device 1 of the present embodiment, after the mixed gas is led out from each of the raw material containers 2A and 2B to the mixed gas-lead-out path L2, the mixed gas can be supplied to the film forming apparatus 100 at the subsequent stage.

In the mixed gas supply device 1 of the present embodiment, the carrier gas-introduction path L1 and the mixed gas-lead-out path L2 are connected to the raw material container 2, so that the carrier gas can be introduced from the carrier gas-introduction path L1 into the raw material container 2 (2A, 2B), and the gas of the film forming material S accompanying the carrier gas can be discharged as the mixed gas to the mixed gas-lead-out path L2.

When introducing the carrier gas into the raw material container 2, the carrier gas may be supplied by bubbling, or the carrier gas may be supplied to the gas phase inside the container (that is, the vapor of the film forming material S).

The mixed gas contains at least one of the gas of the film forming material S as a main component. The mixed gas may contain the carrier gas. The main components of the mixed gas are preferably a nitrogen containing compound or a metal containing compound and a carrier gas, from the viewpoint of high vapor pressure and ease in controlling the concentration.

The pipe heater (second heater) 6 is provided to cover the surfaces of the pipe that constitutes the branched paths L1A, L1B subsequent to the carrier gas-flow rate control device 5 of the carrier gas-introduction path L1 and the mixed gas-lead-out path L2 (L2A, L2B), and heats the carrier gas-introduction path L1 and the mixed gas-lead-out path L2.

The pipe heater-temperature adjusting device (second heater adjusting device) 7 is not particularly limited as long as it can adjust (control) the output of the pipe heater 6. Note that the pipe heater-temperature adjusting device 7 only needs to have a function of adjusting (controlling) the output of the pipe heater 6, and may be integrated with the pipe heater 6.

The temperature of the pipes constituting the flow paths of the carrier gas and the mixed gas must be a temperature at which the gas of the film forming material S does not re-liquefy or re-solidify, and is therefore preferably higher than the temperature of the raw material container 2. This makes it possible to prevent re-liquefaction of the film forming material S in the mixed gas-lead-out path L2, and allows the mixed gas containing the gas of the film forming material S to flow safely and stably through the mixed gas-lead-out path L2.

The bypass path L3 is a flow path that branches off from the carrier gas-introduction path L1, makes a detour without passing through the raw material container 2, and merges with the mixed gas-lead-out path L2. In the mixed gas supply device 1 of the present embodiment, the bypass path L3A branches off from the carrier gas-introduction path L1A, makes a detour without passing through the raw material container 2A, and merges with the mixed gas-lead-out path L2A. Similarly, the bypass path L3B branches off from the carrier gas-introduction path LIB, makes a detour without passing through the raw material container 2B, and merges with the mixed gas-lead-out path L2B.

By selecting the bypass path L3 (L3A, L3B) as the flow path, the carrier gas flowing through the carrier gas-introduction path L1 can be supplied to the mixed gas-lead-out path L2 on the secondary side of the raw material container 2 without being introduced into the raw material container 2. In addition, when removing gas (residual gas) containing the film forming material S remaining in the mixed gas-lead-out path L2, the residual gas can be efficiently purged and removed by supplying the carrier gas through the bypass path L3 (L3A, L3B).

In the mixed gas supply device 1 of the present embodiment, it is preferable that one or more on-off valves be provided in each path, and by appropriately selecting the on-off state of the on-off valves, any flow path can be formed according to the purpose.

The first pressure measuring device 11 is located in the mixed gas-lead-out path L2 and measures the pressure in the raw material container 2 (2A, 2B). By determining the pressure in the raw material container 2, it is possible to know the remaining amount of the film forming material S and to find an abnormality in the container.

The pressure adjusting device 8 is located in the mixed gas-lead-out path L2 and adjusts the pressure in the raw material container 2 (2A, 2B). The pressure adjusting device 8 is not particularly limited as long as it can adjust the pressure in the raw material container 2 based on the pressure in the raw material container 2. Examples of the pressure adjusting device 8 include a back pressure valve (back pressure adjusting device; BPR), an auto pressure adjusting device, a piezoelectric valve, and a pressure control system.

The pressure adjusting device 8 may be a device in which the pressure measuring device and pressure control valve are integrated, or the pressure measuring device and pressure control valve may be separate devices.

When they are separate devices, for example, a first pressure measuring device 11 that measures the pressure inside the raw material container 2 and a pressure control valve (an adjustable opening/closing valve, a butterfly valve, and the like) are used, and the pressure inside the raw material container 2 is adjusted by linking them together.

The mixed gas-measuring device 9 is located in the mixed gas-lead-out path L2 on the secondary side of the pressure adjusting device 8, and is a device that measures the concentration or flow rate of the mixed gas flowing through the mixed gas-lead-out path L2. The mixed gas-measuring device 9 is not particularly limited, but is preferably selected from a gas concentration analysis device that can measure the concentration of the film forming material S in the mixed gas, or a flow rate measuring device that can measure the flow rate of the mixed gas.

Examples of gas concentration measuring devices that can be used as the mixed gas-measuring device 9 include FT-IR, ND-IR, ultrasonic gas concentration meters, gas concentration sensors, and laser gas concentration meters.

Examples of flow rate measuring devices that can be used as the mixed gas-measuring device 9 include a mass flow meter (MFM) and a flow sensor. When a flow rate measuring device is used as the mixed gas-measuring device 9, the flow rate and mixing ratio (concentration of the mixed gas) of the gas of the film forming material S in the mixed gas can be calculated based on the flow rate value of the carrier gas controlled by the carrier gas-flow rate control device 5 and the measurement value of the flow rate measuring device.

The first buffer tank (buffer tank) 10 is located in the mixed gas-lead-out path L2 on the secondary side of the mixed gas-measuring device 9, and is a container that temporarily stores the mixed gas flowing through the mixed gas-lead-out path L2.

The first buffer tank 10 is located in the mixed gas-lead-out path L2 on the secondary side of the mixed gas-measuring device 9, which has the effect of homogenizing the concentration of the mixed gas.

The first buffer tank 10 is not particularly limited as long as it is a sealed container that can store mixed gas. In addition, the capacity of the first buffer tank 10 is not particularly limited, but a tank with a capacity of 1 to 100 L can be used, and a tank with a capacity of 10 to 50 L is preferable.

In the mixed gas supply device 1 of the present embodiment, the first buffer tank 10 is located in the mixed gas-lead-out path L2 through a branch path, so that when performing maintenance such as replacing or cleaning the first buffer tank 10, it is possible to prevent atmospheric components from entering the mixed gas lead-out path L2.

In the mixed gas supply device 1 of the present embodiment, the first buffer tank 10 is located in the mixed gas-lead-out path L2 through a branch path, but the present embodiment is not limited to this embodiment, For example, the first buffer tank 10 may be provided in the mixed gas-lead-out path L2 without a branch path.

The second pressure measuring device (pressure gauge) 12 measures the pressure inside the first buffer tank 10. The second pressure measuring device 12 is preferably provided in a position close to the first buffer tank 10. This allows any abnormality in the pressure inside the first buffer tank 10 to be immediately detected and a safety device (not shown) to be activated.

The detector 13 constitutes a part of the safety mechanism in the mixed gas supply device 1 of the present embodiment. Examples of the detector 13 include a gas leak detector and a liquid leak detector. By linking the detector 13 with a safety device (not shown), the supply of each gas can be automatically cut off in the event of an emergency such as a leak or liquid leak.

In the mixed gas supply device 1 of the present embodiment, a signal can be transmitted and received by wire or wireless connection between the pressure adjusting device 8 and the mixed gas-measuring device 9. As a result, the mixed gas supply device 1 of the present embodiment can adjust the concentration of the gas of the film forming material S in the mixed gas to a required value by manually or automatically controlling the pressure in the raw material container 2 (2A, 2B) by the pressure adjusting device 8 while monitoring the mixture ratio of the carrier gas and the gas of the film forming material S in the mixed gas by the mixed gas-measuring device 9.

Specifically, if the measured value of the concentration of the mixed gas obtained by the mixed gas-measuring device 9 is lower than the set concentration (set value) in the pressure adjusting device 8, or if the measured value of the concentration of the mixed gas obtained decreases as the mixed gas is supplied, a control signal for updating the set pressure value is sent from the mixed gas-measuring device 9 to the pressure adjusting device 8. This instantly adjusts the opening of the pressure adjusting device 8 in the opening direction, and the mixed gas having the set concentration is supplied with good responsiveness.

When manually controlling the pressure inside the raw material container 2, the pressure adjusting device 8 is manually operated to update the set pressure value inside the raw material container 2 so that the concentration measured by the mixed gas-measuring device 9 matches the set concentration.

Unlike manual control, automatic control is preferable because it allows the pressure inside the raw material container 2 to be adjusted instantly.

Therefore, according to the mixed gas supply device 1 of the present embodiment, the mixed gas containing at least one kind of a gas of the forming material S can be supplied, for example, as a part of the raw material gas to a downstream film forming apparatus 100 by adjusting the concentration of the film forming material S in the mixed gas.

Moreover, according to the mixed gas supply device 1 of the present embodiment, since the mixed gas-lead-out path L2 is provided with the first buffer tank 10, the mixed gas flowing through the mixed gas-lead-out path L2 can be temporarily stored in the first buffer tank 10 and then supplied to the secondary side. In this way, since the mixed gas is supplied through the first buffer tank 10, pressure fluctuations that occur during supply can be suppressed, and the concentration and flow rate of the mixed gas can be stabilized.

### Second Embodiment

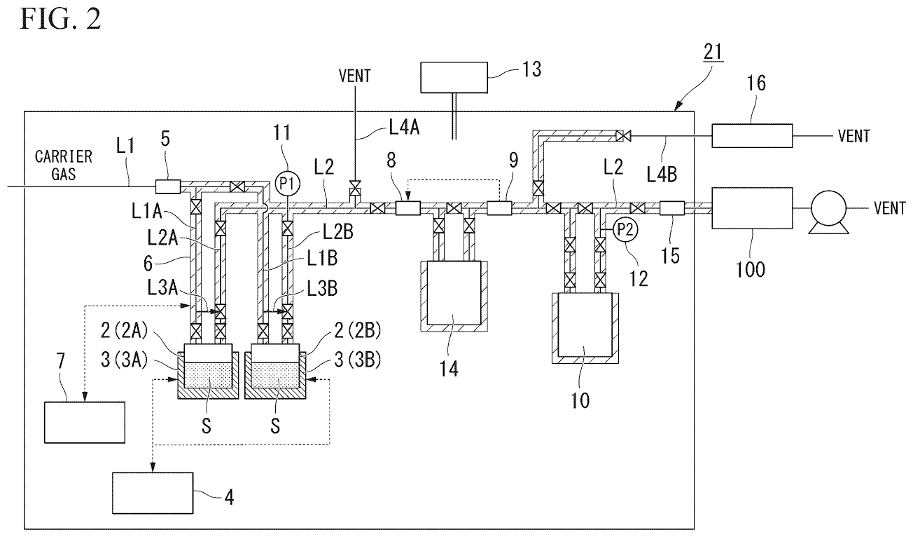

FIG. 2 is a system diagram showing the configuration of a second embodiment of the mixed gas supply device of the present invention.

As shown in FIG. 2, the mixed gas supply device 21 of the second embodiment differs from the mixed gas supply device 1 of the first embodiment in that it further includes a second buffer tank 14, a mixed gas-flow rate control device 15, a vacuum pump 16, and exhaust paths L4A and LAB, but the other configurations are the same. Therefore, in the mixed gas supply device 21 of the present embodiment, the same components as those of the mixed gas supply device 1 are given the same reference numerals, and their description will be omitted.

The second buffer tank 14 is located between the pressure adjusting device 8 and the mixed gas-measuring device 9 in the mixed gas-lead-out path L2, and is a container that temporarily stores the mixed gas flowing through the mixed gas-lead-out path L2.

By placing the second buffer tank 14 between the pressure adjusting device 8 and the mixed gas-measuring device 9 in the mixed gas-lead-out path L2, pressure fluctuations and flow rate fluctuations in the mixed gas-measuring device 9 can be suppressed.

The second buffer tank 14 is not particularly limited as long as it is a sealed container that can store the mixed gas. In addition, the capacity of the second buffer tank 14 is not particularly limited, but a tank with a capacity of 1 to 100 L can be used, and a tank with a capacity of 1 to 20 L is preferable.

In the mixed gas supply device 21 of the present embodiment, the second buffer tank 14 is located in the mixed gas-lead-out path L2 through a branch path, so that when performing maintenance such as replacing or cleaning the second buffer tank 14, it is possible to prevent atmospheric components from entering the mixed gas-lead-out path L2.

In the mixed gas supply device 21 of the present embodiment, the second buffer tank 14 is located in the mixed gas-lead-out path L2 through a branch path, but the present embodiment is not limited to this embodiment. For example, the second buffer tank 14 may be provided in the mixed gas-lead-out path L2 without a branch path.

The mixed gas-flow rate control device 15 is located in the mixed gas-lead-out path L2 on the secondary side of the first buffer tank 10, and controls the flow rate of the mixed gas adjusted to a set concentration.

According to the mixed gas supply device 21 of the present embodiment, since the mixed gas-flow rate control device 15 is provided in the mixed gas-lead-out path L2, even if pressure fluctuations occur upstream in order to control the concentration, or pressure fluctuations occur downstream in the reaction furnace of the film formation apparatus 100, the mixed gas can be stably supplied at the set flow rate.

Furthermore, according to the mixed gas supply device 21 of the present embodiment, since the first buffer tank 10 is located upstream (primary side) of the mixed gas-flow rate control device 15, sudden pressure fluctuations that occur when the pressure in the raw material container 2 is controlled by the pressure adjusting device 8 can be effectively suppressed.

The exhaust paths L4A and L4B are flow paths branching from the mixed gas-lead-out path L2 and for exhausting the mixed gas in the mixed gas-lead-out path L2. By providing the vacuum pump 16 in each of the exhaust paths L4A and L4B, the mixed gas in the mixed gas-lead-out path L2 can be evacuated to a vacuum.

According to the mixed gas supply device 21 of the present embodiment, the mixed gas-lead-out path L2 is provided with an exhaust path L4A on the primary side of the pressure adjusting device 8. Therefore, by repeating a process of filling the pressure with the carrier gas and a process of evacuating to a vacuum before replacing the raw material container 2, the mixed gas including the gas of the film forming material S remaining in the mixed gas-lead-out path L2 can be efficiently purged and removed.

Furthermore, according to the mixed gas supply device 21 of the present embodiment, the mixed gas-lead-out path L2 is provided with the exhaust path LAB on the secondary side of the mixed gas-measuring device 9, so that the mixed gas remaining on the secondary side of the mixed gas-measuring device 9 can be efficiently purged and removed.

As a purging method, instead of the method of repeating cycle purging, a method of continuously circulating the carrier gas may be applied.

The vacuum pump 16 is not particularly limited, but examples thereof include a dry vacuum pump, a diaphragm pump, a turbo molecular pump, a scroll pump, an oil rotary pump, and a vacuum generator.

According to the mixed gas supply device 21 of the present embodiment, similarly to the mixed gas supply device 1 described above, while the mixed gas-measuring device 9 monitors the mixture ratio of the carrier gas and the gas of the film forming material S in the mixed gas, while the pressure adjusting device 8 controls the pressure inside the raw material container 2 (2A, 2B), so that the mixed gas adjusted to a predetermined gas concentration can be stably supplied to the downstream film forming apparatus 100 as part of the raw material gas.

Furthermore, according to the mixed gas supply device 21 of the present embodiment, the mixed gas-lead-out path L2 is provided with the first buffer tank 10 and the second buffer tank 14, and therefore the mixed gas is supplied through the first buffer tank 10 and the second buffer tank 14. This makes it possible to suppress pressure fluctuations that occur during supply, and to stabilize the concentration and flow rate of the mixed gas.

Furthermore, according to the mixed gas supply device 21 of the present embodiment, one or more exhaust paths L4A and L4B are provided in the mixed gas-lead-out path L2, so that the mixed gas remaining in the mixed gas-lead-out path L2 can be purged before replacing the raw material container 2 or before opening the piping for maintenance. This allows the raw material container 2 to be safely replaced and maintained.

Moreover, according to the mixed gas supply device 21 of the present embodiment, since the mixed gas-lead-out path L2 is provided with the mixed gas-flow rate control device 15, even if there is a pressure fluctuation caused by controlling the concentration on the upstream side or a pressure fluctuation caused in the reactor of the film forming apparatus 100 on the downstream side, the mixed gas can be stably supplied at the set flow rate. As a result, the mixed gas can be supplied at a stable flow rate to the film forming apparatus 100 located on the secondary side of the mixed gas supply device 21.

### Third Embodiment

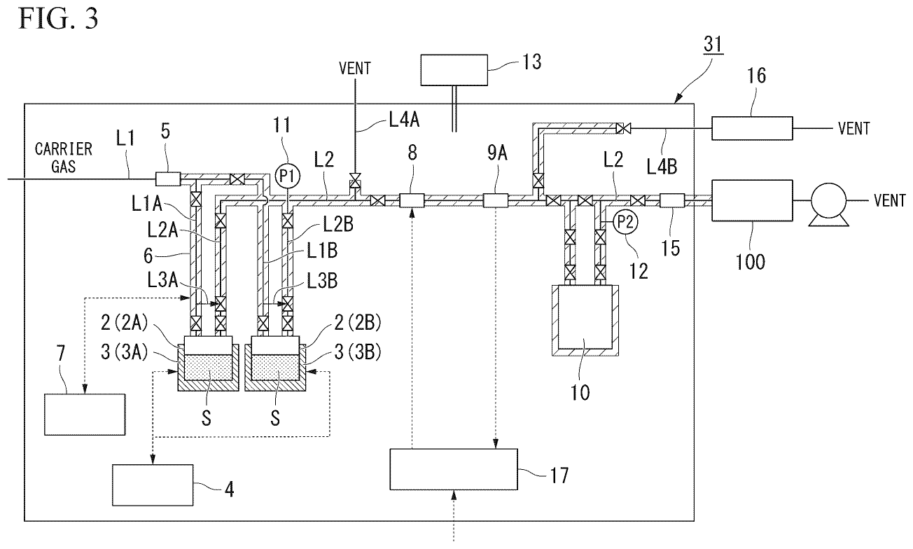

FIG. 3 is a system diagram showing the configuration of a third embodiment of the mixed gas supply device of the present invention.

As shown in FIG. 3, the mixed gas supply device 31 of the third embodiment differs from the mixed gas supply device 21 of the second embodiment in that the mixed gas-measuring device 9 is a mixed gas-concentration analysis device 9A and a mixed gas-concentration adjusting device 17 is provided instead of the second buffer tank 14, but the other configurations are the same. Therefore, in the mixed gas supply device 31 of the present embodiment, the same components as those of the mixed gas supply device 21 are given the same reference numerals, and their description will be omitted.

The mixed gas-concentration adjusting device 17 is a control device that adjusts the concentration of the film forming material S in the mixed gas to a set value.

The mixed gas-concentration adjusting device 17 is capable of transmitting and receiving a signal to and from the pressure adjusting device 8 and the mixed gas-concentration analysis device 9A through wired or wireless connection. Specifically, the mixed gas-concentration adjusting device 17 receives a measured value from the mixed gas-concentration analysis device 9A and transmits a control signal to the pressure adjusting device 8.

The mixed gas-concentration adjusting device 17 can also set the concentration of film forming material S in the mixed gas as a set value. The set value may be directly input to the mixed gas-concentration adjusting device 17 by an operator, or a signal may be transmitted through wired or wireless connection.

In addition, the mixed gas-concentration adjusting device 17 has the function of calculating the difference between the measured value of the concentration of the mixed gas obtained by the mixed gas-concentration analysis device 9A and the set value in the mixed gas-concentration adjusting device 17, and updating the set pressure value of the pressure adjusting device 8 based on the obtained difference so that the measured value (actual value) becomes the set value.

Specifically, if the measured value of the concentration of the mixed gas obtained by the mixed gas-concentration analysis device 9A is lower than the set concentration (set value) in the mixed gas-concentration adjuster 17, or if the measured value of the concentration of the mixed gas obtained decreases as the mixed gas is supplied, a control signal for updating the set pressure value is sent from the mixed gas-concentration adjuster 17 to the pressure adjusting device 8. This instantly adjusts the opening of the pressure adjusting device 8 in the opening direction, and the mixed gas having the set concentration is supplied with good responsiveness.

Similarly, if the measured value of the concentration of the mixed gas obtained increases, the mixed gas-concentration adjuster 17 transmits a control signal to the pressure adjusting device 8 to update the set pressure value. This instantly adjusts the opening of the pressure adjusting device 8 in the closing direction, and the mixed gas having the set concentration is supplied with good responsiveness.

According to the mixed gas supply device 31 of the present embodiment, it is possible to achieve the same effects as the mixed gas supply devices 1 and 21 described above.

Furthermore, the mixed gas supply device 31 of the present embodiment is equipped with a mixed gas-concentration adjusting device 17 capable of transmitting and receiving a signal between the pressure adjusting device 8 and the mixed gas-concentration analysis device 9A, so that even if there is a concentration fluctuation at the initial stage of mixed gas supply or a vapor pressure fluctuation due to a decrease in material temperature during continuous supply, the mixed gas having the set concentration (set value) in the mixed gas-concentration adjusting device 17 can be stably supplied.

### Fourth Embodiment

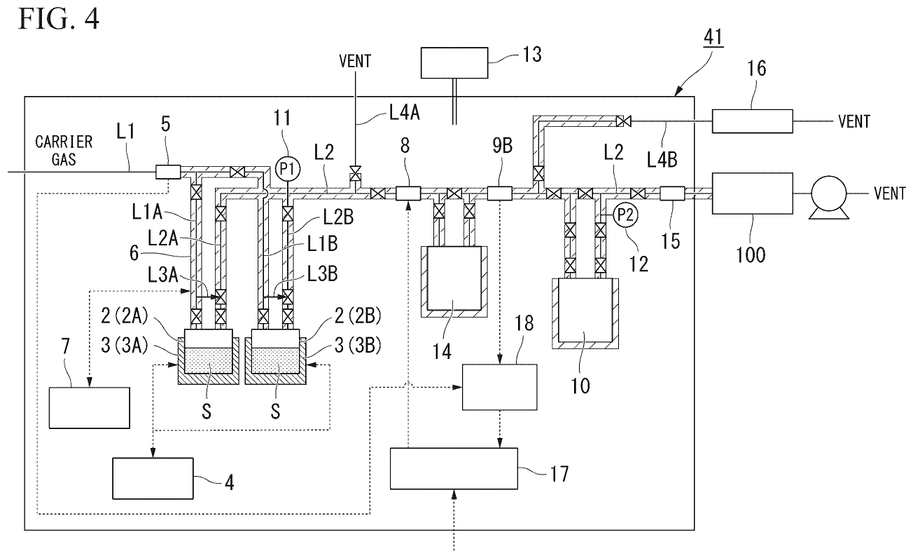

FIG. 4 is a system diagram showing the configuration of a fourth embodiment of the mixed gas supply device of the present invention.

As shown in FIG. 4, the mixed gas supply device 41 of the fourth embodiment differs from the mixed gas supply device 21 of the second embodiment in that the mixed gas-measuring device 9 is a mixed gas-flow rate measuring device 9B, and the mixed gas-concentration adjusting device 17 and the mixed gas-concentration calculation device 18 are further included, but the other configurations are the same. Therefore, in the mixed gas supply device 41 of the present embodiment, the same components as those of the mixed gas supply device 21 are given the same reference numerals, and their description will be omitted.

The mixed gas-concentration calculation device 18 is a calculation device that calculates the concentration of the film forming material S in the mixed gas. The mixed gas-concentration calculation device 18 is capable of transmitting and receiving a signal to and from the carrier gas-flow rate control device 5, the mixed gas-flow rate measuring device 9B, and the mixed gas-concentration adjusting device 17 through wired or wireless connection.

Specifically, the mixed gas-concentration calculation device 18 receives the set value of the flow rate of the carrier gas in the carrier gas-flow rate control device 5 and the measurement value (actual value) of the flow rate of the mixed gas measured by the mixed gas-flow rate measuring device 9B, and calculates the concentration of the film forming material S in the mixed gas based on these values. Then, the mixed gas-concentration calculation device 18 transmits the concentration (calculated value) obtained by the above-mentioned calculation to the mixed gas-concentration adjusting device 17.

The mixed gas-concentration adjusting device 17 is a control device that adjusts the concentration of the film forming material S in the mixed gas to a set value.

The mixed gas-concentration adjusting device 17 is capable of transmitting and receiving a signal to the pressure adjusting device 8 and the mixed gas-concentration calculation device 18 through wired or wireless connection. Specifically, the mixed gas-concentration adjusting device 17 receives a calculated concentration value from the mixed gas-concentration calculation device 18 and transmits a control signal to the pressure adjusting device 8.

The mixed gas-concentration adjusting device 17 can also set the concentration of the film forming material S in the mixed gas as a set value. The set value may be directly input to the mixed gas-concentration adjusting device 17 by an operator, or a signal may be transmitted through wired or wireless connection.

In addition, the mixed gas-concentration adjusting device 17 has the function of calculating the difference between the calculated value of the concentration of the mixed gas obtained by the mixed gas-concentration calculation device 18 and the set value in the mixed gas-concentration adjusting device 17, and updating the set pressure value of the pressure adjusting device 8 based on the obtained difference so that the calculated value becomes the set value.

Specifically, if the measured value of the concentration of the mixed gas obtained by the mixed gas-concentration calculation device 18 is lower than the set concentration (set value) in the mixed gas-concentration adjuster 17, or if the measured value of the concentration of the mixed gas obtained decreases as the mixed gas is supplied, the mixed gas-concentration adjuster 17 transmits a control signal to the pressure adjusting device 8 to update the set pressure value. This instantly adjusts the opening of the pressure adjusting device 8 in the opening direction, and the mixed gas having the set concentration is supplied with good responsiveness.

Similarly, if the measured value of the concentration of the mixed gas obtained increases, the mixed gas-concentration adjusting device 18 transmits a control signal to the pressure adjusting device 8 to update the set pressure value. This instantly adjusts the opening of the pressure adjusting device 8 in the closing direction, and the mixed gas having the set concentration is supplied with good responsiveness.

According to the mixed gas supply device 41 of the present embodiment, it is possible to achieve the same effects as the mixed gas supply devices 1 and 21 described above.

In addition, the mixed gas supply device 41 of the present embodiment is equipped with a mixed gas-concentration adjusting device 17 that can transmit and receive a signal to and from the pressure adjusting device 8 and the mixed gas-concentration calculation device 18, so that even if there is a concentration fluctuation at the initial stage of mixed gas supply or a vapor pressure fluctuation due to a decrease in material temperature during continuous supply, the mixed gas having the set concentration (set value) in the mixed gas-concentration adjusting device 17 can be stably supplied.

Furthermore, according to the mixed gas supply device 41 of the present embodiment, the second buffer tank 14 is provided between the pressure adjusting device 8 and the mixed gas-flow rate measuring device 9B, so that flow rate fluctuations and pressure fluctuations that occur when the pressure adjusting device 8 controls the pressure inside the raw material container 2 can be suppressed, and the mixed gas of a required concentration can be stably supplied.

### Fifth Embodiment

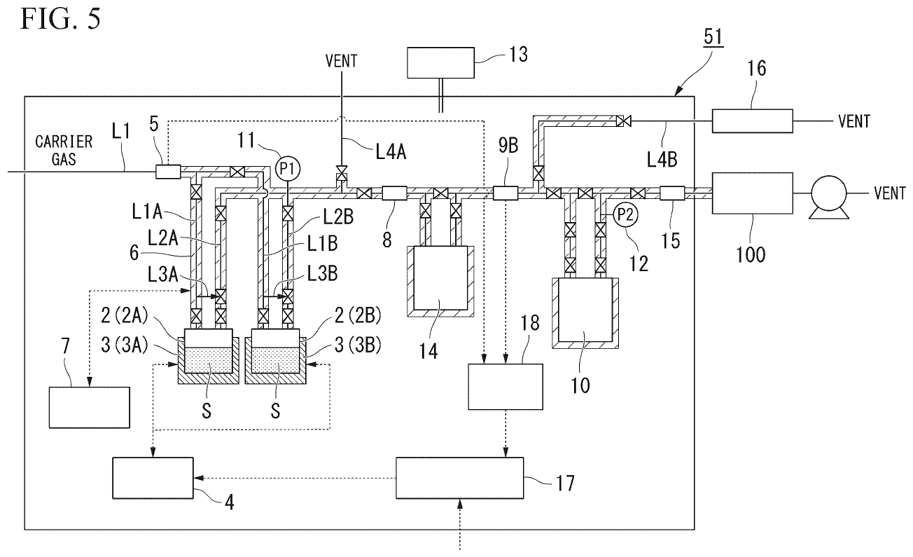

FIG. 5 is a system diagram showing the configuration of a fifth embodiment of the mixed gas supply device of the present invention.

As shown in FIG. 5, the mixed gas supply device 51 of the fifth embodiment differs from the mixed gas supply device 41 of the forth embodiment in that the mixed gas-concentration adjusting device 17 transmits a control signal to the container heater-temperature adjusting device 4 instead of the pressure adjusting device 8, but the other configurations are the same. Therefore, in the mixed gas supply device 51 of the present embodiment, the same components as those of the mixed gas supply device 41 are given the same reference numerals, and their description will be omitted.

The mixed gas-concentration adjusting device 17 is a control device that adjusts the concentration of the film forming material S in the mixed gas to a set value.

The mixed gas-concentration adjusting device 17 is capable of transmitting and receiving a signal to and from the container heater-temperature adjusting device 4 and the mixed gas-concentration calculation device 18 through wired or wireless connection. Specifically, the mixed gas-concentration adjusting device 17 receives a calculated concentration value from the mixed gas-concentration calculation device 18 and transmits a control signal to the container heater-temperature adjusting device 4.

The mixed gas-concentration adjusting device 17 can also set the concentration of the film forming material S in the mixed gas as a set value. The set value may be directly input to the mixed gas-concentration adjusting device 17 by an operator, or a signal may be transmitted through wired or wireless connection.

In addition, the mixed gas-concentration adjusting device 17 has a function of calculating the difference between the calculated value of the concentration of the mixed gas obtained by the mixed gas-concentration calculation device 18 and the set value in the mixed gas-concentration adjusting device 17, and updating the set value of the output of the container heater-temperature adjusting device 4 based on the obtained difference so that the calculated value becomes the set value.

Specifically, if the calculated value of the concentration of the mixed gas obtained by the mixed gas-concentration calculation device 18 is lower than the set concentration (set value) in the mixed gas-concentration adjusting device 17, or if the calculated value of the concentration of the mixed gas decreases as the mixed gas is supplied, the mixed gas-concentration adjusting device 17 transmits a control signal to the container heater-temperature adjusting device 4 to update the set value of the output. The higher the temperature of the raw material container 2, the higher the vapor pressure of the film forming material S, and the concentration of the gas of the film forming material S in the mixed gas can be increased. Therefore, by controlling the output of the container heater 3 (3A, 3B) to increase, the raw material container 2 (2A, 2B) is adjusted to be heated, and the mixed gas having the set concentration can be supplied with good responsiveness.

The mixed gas supply device 51 of the present embodiment includes the mixed gas-concentration adjusting device 17 capable of transmitting and receiving a signal to and from the container heater-temperature adjusting device 4 and the mixed gas-concentration calculation device 18, and therefore can achieve the same effects as the mixed gas supply device 41 described above.

### Modified Fifth Embodiment

The mixed gas supply device of the modified fifth embodiment differs from the mixed gas supply device 51 of the fifth embodiment in that the mixed gas-measuring device 9B is a mixed gas-concentration analysis device 9A and the mixed gas-concentration calculation device 18 will be omitted, but the other configurations are the same.

The mixed gas-concentration adjusting device 17 is capable of transmitting and receiving a signal through wired or wireless connection with the container heater-temperature adjusting device 4 and the mixed gas-concentration analysis device 9 A. Specifically, the mixed gas-concentration adjusting device 17 receives a measured value of the concentration of the mixed gas obtained by the mixed gas-concentration analysis device 9A and transmits a control signal to the container heater-temperature adjusting device 4.

In addition, the mixed gas-concentration adjusting device 17 has the function of calculating the difference between the measured value of the concentration of the mixed gas obtained by the mixed gas-concentration analysis device 9A and the set value in the mixed gas-concentration adjusting device 17, and updating the set value of the output of the container heater-temperature adjusting device 4 based on the obtained difference so that the measured value (actual value) becomes the set value.

Specifically, if the measured value of the concentration of the mixed gas obtained by the mixed gas-concentration analysis device 9A is lower than the set concentration (set value) in the mixed gas-concentration adjusting device 17, or if the measured value of the concentration of the mixed gas obtained decreases as the mixed gas is supplied, a control signal is sent from the mixed gas-concentration adjusting device 17 to the container heater-temperature adjusting device 4 to update the output set value.

The higher the temperature of the raw material container 2, the higher the vapor pressure of the film forming materials S, and the higher the gas concentration of the film forming material S in the mixed gas can be achieved. Therefore, by controlling the output of the container heater 3 (3A, 3B) to increase, the raw material container 2 (2A, 2B) is adjusted to be heated, and the mixed gas having the set concentration can be supplied with good responsiveness.

According to the modified mixed gas supply device 51 of the present embodiment, the mixed gas-concentration adjusting device 17 capable of transmitting and receiving a signal to and from the container heater-temperature adjusting device 4 and the mixed gas-concentration analysis device 9A is provided, and therefore the same effects as those of the mixed gas supply device 51 described above can be achieved.

### Sixth Embodiment

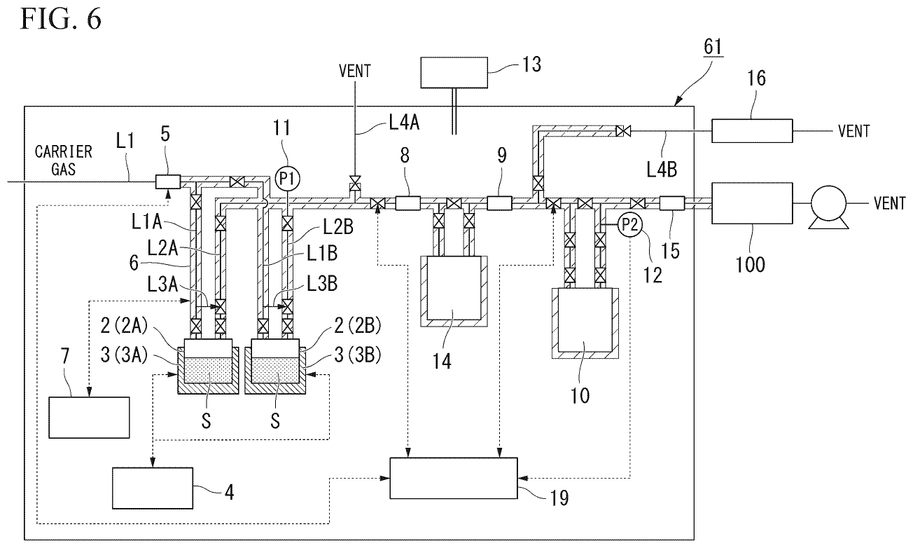

FIG. 6 is a system diagram showing the configuration of a sixth embodiment of the mixed gas supply device of the present invention.

As shown in FIG. 6, the mixed gas supply device 61 of the sixth embodiment differs from the mixed gas supply device 21 of the second embodiment in that it further includes a supply control device 19, but the other configurations are the same. Therefore, in the mixed gas supply device 61 of the present embodiment, the same components as those of the mixed gas supply device 21 are given the same reference numerals, and their description will be omitted.

The supply control device 19 controls the carrier gas-flow rate control device 5 and the opening degree of one or more on-off valves located in the mixed gas-lead-out path L2.

The supply control device 19 is capable of transmitting and receiving a signal by wire or wireless connection to and from the carrier gas-flow rate control device 5, one or more on-off valves located in the mixed gas-lead-out path L2, and the second pressure measuring device (pressure gauge) 12. Specifically, the supply control device 19 receives a measured value of the pressure in the first buffer tank 10 from the second pressure measuring device 12, and transmits a control signal to the carrier gas-flow rate control device 5 and the one or more on-off valves.

Specifically, the supply control device 19 controls the set value of the flow rate (or stop of supply) of the carrier gas of the carrier gas-flow rate control device 5 and the opening degree of the one or more on-off valves based on the measured value of the second pressure measuring device 12, thereby controlling the measured value of the second pressure measuring device 12 (that is, the pressure in the first buffer tank 10) to a required value.

If the pressure in the first buffer tank 10 is lower than the set pressure value, the second pressure gauge 12 transmits a control signal to the carrier gas-flow rate control device 5 to start supply, and a control signal to the one or more on-off valves located in the mixed gas lead-out path L2 to open. In this way, by instantly controlling the supply stop of the carrier gas-flow rate control device 5 and the opening (opening/closing) of the one or more on-off valves according to the measurement value of the second pressure measuring device 12, the pressure in the first buffer tank 10 can be controlled to a required value.

In the mixed gas supply device 61 of the present embodiment, the flow rate of the mixed gas may vary significantly in the mixed gas-lead-out path L2 due to pressure fluctuations that occur in order to control the concentration of the mixed gas, pressure fluctuations that occur in the reactor of the film forming apparatus 100, and the like.

By providing a mixed gas-flow rate control device 15 in the mixed gas-lead-out path L2, the mixed gas having the set flow rate is stably supplied, regardless of whether pressure fluctuations occur upstream or downstream of the mixed gas-flow rate control device 15.

In other words, by controlling the pressure upstream of the mixed gas-flow rate control device 15 in the mixed gas-lead-out path L2 to be within a predetermined range, the mixed gas flowing through the mixed gas-lead-out path L2 can be controlled to a stable flow rate.

In particular, when the first buffer tank 10 is installed upstream of the mixed gas-flow rate control device 15 in the mixed gas-lead-out path L2, this is more preferable, since it is possible to suppress the effects of sudden pressure fluctuations that occur when the pressure in the raw material container 2 is controlled by the pressure adjusting device 8.

The mixed gas supply device 61 of the present embodiment includes the supply control device 19 that is linked to the carrier gas-flow rate control device 5, the one or more on-off valves located in the mixed gas-lead-out path L2, and the second pressure measuring device (pressure gauge) 12, and controls the pressure in the first buffer tank 10 upstream of the mixed gas-flow rate control device 15 to be within a predetermined range, so that the mixed gas flowing through the mixed gas-lead-out path L2 can be controlled to a stable flow rate.

As described above, according to the mixed gas supply devices 1, 21, 31, 41, 51, and 61 of the first to sixth embodiments, the mixed gas containing the gas of the film forming material S can be supplied safely and stably.

When using the mixed gas supply devices 1, 21, 31, 41, 51, and 61 of the first to sixth embodiments described above, it is preferable that the H₂O concentration contained in the mixed gas be 0.1 ppm or less.

If the water concentration in the mixed gas is high, the mixed gas supply devices 1, 21, 31, 41, 51, and 61 may include a purifier that includes an adsorbent, a separation membrane, or the like.

The technical scope of the present invention is not limited to the embodiments above, and various modifications can be made without departing from the spirit of the present invention.

### EXAMPLES

The present invention will be described in more detail below using examples, but the present invention is not limited to these examples,

### Example 1

A mixed gas supply test was conducted using the mixed gas supply device 1 shown in FIG. 1 as a mixed gas supply device. The test conditions were as follows:
Carrier gas: Nitrogen (N₂)
Flow rate of carrier gas: 3000 sccm
Film forming material S: Hydrazine (N₂H₄)
Concentration of film forming material S in mixed gas (concentration of the mixed gas): 5% by volume
Pressure inside the container: Pressure adjusting device 8 was controlled based on the measured value of the concentration of the mixed gas obtained by the mixed gas-measuring device 9

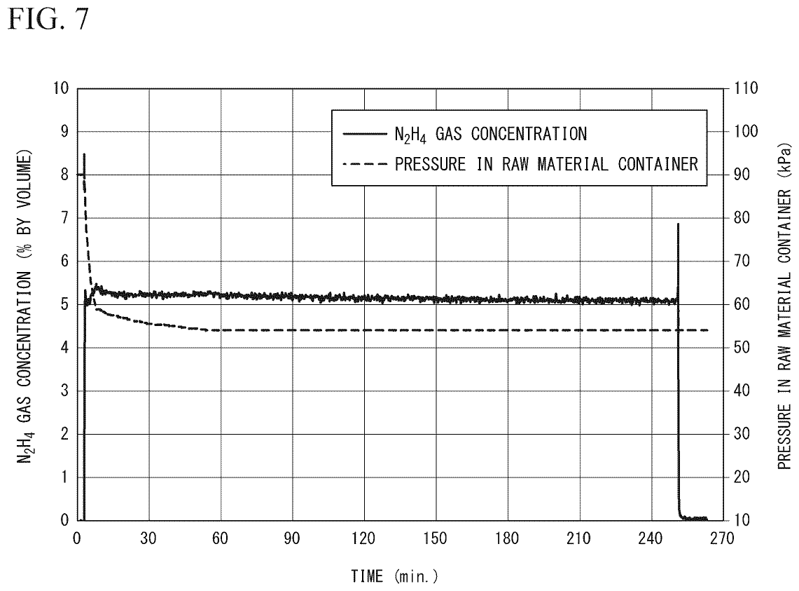

The results are shown in FIG. 7. In FIG. 7, the X-axis represents the supply time (min), the first Y-axis represents the concentration (% by volume) of N₂H₄ gas which is a mixed gas, and the second Y-axis represents the pressure (kPa) inside the container.

As shown in FIG. 7, by installing the first buffer tank 10 and adjusting the pressure inside the raw material container 2 with the pressure adjusting device 8, it was possible to stably supply a mixed gas with a concentration of 5% by volume.

### Comparative Example 1

A mixed gas supply test was conducted using a mixed gas supply device that was the same as the mixed gas supply device 1 shown in FIG. 1 except that the first buffer tank 10 was omitted. The test conditions were as follows:
Carrier gas: Nitrogen (N₂)
Flow rate of carrier gas: 1000 sccm
Film forming material S: Hydrazine (N₂H₄)
Concentration of film forming material S in mixed gas (concentration of the mixed gas): 5% by volume
Pressure inside the container: 30 kPa

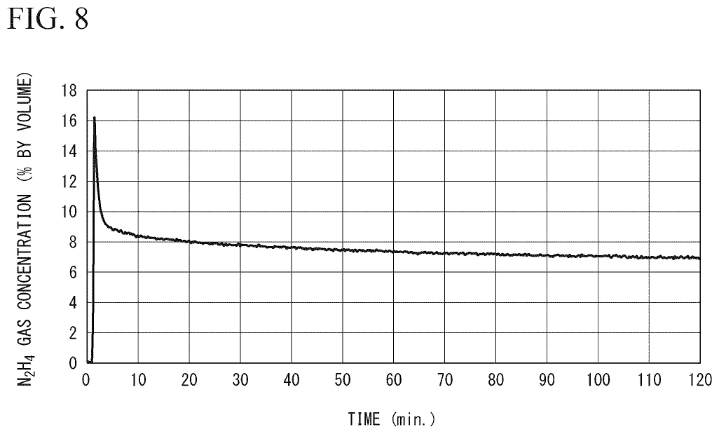

The results are shown in FIG. 8. In FIG. 8, the X-axis indicates the supply time (min), and the Y-axis indicates the concentration (% by volume) of N₂H₄ gas which is a mixed gas.

As shown in FIG. 8, in Comparative Example 1, which did not have the first buffer tank 10 and did not adjust the pressure inside the raw material container 2, the concentration of the mixed gas could not be stably supplied at 5% by volume.

Specifically, immediately after supply, the concentration of the gas of the film forming material S in the mixed gas fluctuated greatly and was not constant. This is because the gas of the film forming material S equivalent to the vapor pressure that had accumulated in the raw material container 2 was discharged together with the carrier gas, resulting in a high concentration immediately after supply.

In addition, when the mixed gas was supplied for a long period of time, the concentration of the gas of the film forming material S in the mixed gas decreased. This is because the vapor pressure of hydrazine decreased due to the heat of vaporization in the raw material container 2 during the supply of the mixed gas.

### Example 2

A mixed gas supply test was conducted using the mixed gas supply device 31 shown in FIG. 3 as the mixed gas supply device. The test conditions were as follows:
Carrier gas: Nitrogen (N₂)
Flow rate of carrier gas: 3000 sccm
Film forming material S: Hydrazine (N₂H₄)
Concentration of film forming material S in mixed gas (concentration of the mixed gas): 5% by volume
Pressure inside the container: The mixed gas-concentration adjusting device 17 automatically controls the pressure adjusting device 8 based on the measured value of the concentration of the mixed gas obtained by the mixed gas-measuring device 9

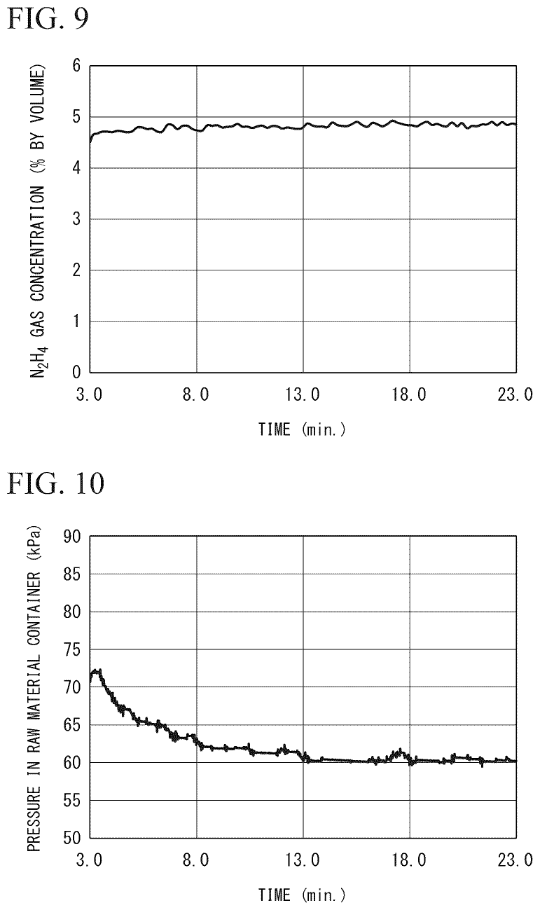

The results are shown in FIGS. 9 and 10. In FIG. 9, the X-axis shows the supply time (min) and the Y-axis shows the concentration (% by volume) of N₂H₄ gas which is a mixed gas. In FIG. 10, the X-axis shows the supply time (min) and the Y-axis shows the pressure (kPa) inside the container.

As shown in FIG. 9, by installing the first buffer tank 10 and automatically adjusting the pressure inside the raw material container 2 with the mixed gas-concentration adjusting device 17, it was possible to stably supply a mixed gas having a concentration of 5% by volume.

As shown in FIG. 10, it was confirmed that the pressure inside the raw material container 2 was gradually reduced by the pressure adjusting device 8 to maintain 5% by volume, which is the set value in the mixed gas-concentration adjusting device 17.

### Example 3

A mixed gas supply test was conducted using the mixed gas supply device 41 shown in FIG. 4 as the mixed gas supply device. The test conditions were as follows:
Carrier gas: Nitrogen (N₂)
Flow rate of Carrier gas: 3000 sccm
Film forming material S: Hydrazine (N₂H₄)
Concentration of film forming material S in mixed gas (concentration of the mixed gas): 5% by volume
Pressure inside the container: The mixed gas-concentration adjusting device 17 automatically controls the pressure adjusting device 8 based on the calculated value of the mixed gas-concentration calculation device 18.

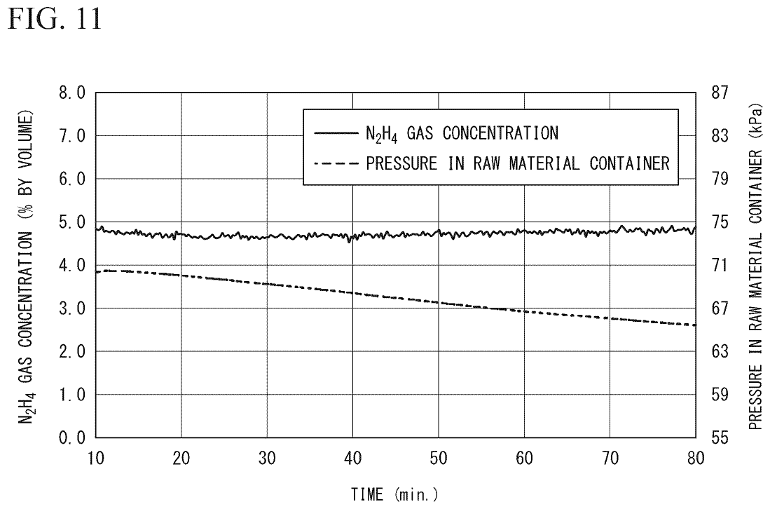

The results are shown in FIG. 11. In FIG. 11, the X-axis shows the supply time (min), the first Y-axis the concentration (% by volume) of N₂H₄ gas which is a mixed gas, and the second Y-axis shows the pressure (kPa) inside the container.

As shown in FIG. 11, by installing the first buffer tank 10 and automatically adjusting the pressure inside the raw material container 2 with the mixed gas-concentration adjusting device 17, it was possible to stably supply a mixed gas having a concentration of 5% by volume.

As also shown in FIG. 11, it was confirmed that the pressure inside the raw material container 2 was gradually reduced by the pressure adjusting device 8 to maintain 5% by volume, which is the set value in the mixed gas-concentration adjusting device 17.

### Example 4

The mixed gas supply device 61 shown in FIG. 6 was used as the mixed gas supply device, and the flow rate stability was evaluated when the supply process and the stop process were repeated assuming an ALD process. The test conditions were as follows:
Carrier gas: Nitrogen (N₂)
Flow rate of Carrier gas: 3000 sccm
Film forming material S: Hydrazine (N₂H₄)
Flow rate of Mixed gas: 3.00 (slm)
Pressure inside the container: 70 kPa
Supply time: Supply for 30 seconds and stop for 30 seconds
Number of repetitions: 10 times

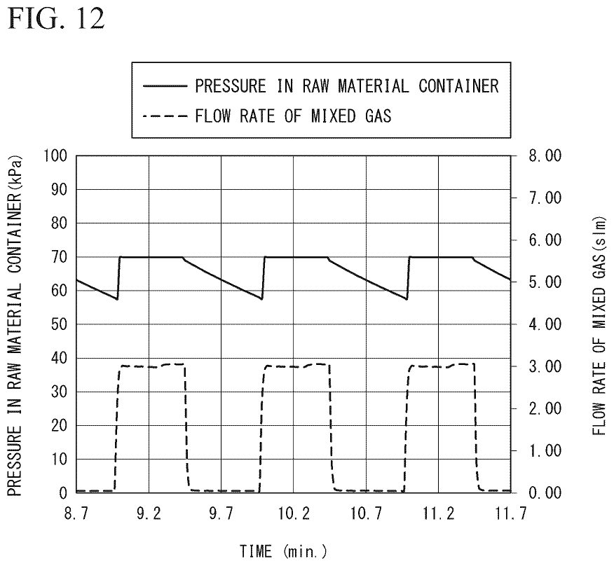

The results are shown in FIG. 12. In FIG. 12, the X-axis represents the supply time (min), the first Y-axis represents the pressure (kPa) inside the container, and the second Y-axis represents the flow rate (slm) of the mixed gas.

As shown in FIG. 12, by installing the first buffer tank 10 and controlling the supply of the carrier gas and the opening and closing of the valve while monitoring the pressure inside the first buffer tank with the supply control device 19, it was possible to stably supply the mixed gas at the set flow rate.

As also shown in FIG. 12, it was confirmed that the pressure inside the raw material container 2 was also stabilized by suppressing pressure fluctuations resulting from the installation of the first buffer tank 10.

### Comparative Example 2

As a mixed gas supply device, a device in which the first buffer tank 10 is omitted from the mixed gas supply device 61 shown in FIG. 6 was used, and the flow rate stability was evaluated when the supply process and the stop process were repeated, assuming an ALD process. The test conditions were as follows.
Carrier gas: Nitrogen (N₂)
Flow rate of Carrier gas: 3000 sccm
Film forming material S: Hydrazine (N₂H₄)
Flow rate of Mixed gas: 3.00 (slm)
Pressure inside the container: 70 kPa
Supply time: Supply for 30 seconds and stop for 30 seconds
Number of repetitions: 10 times

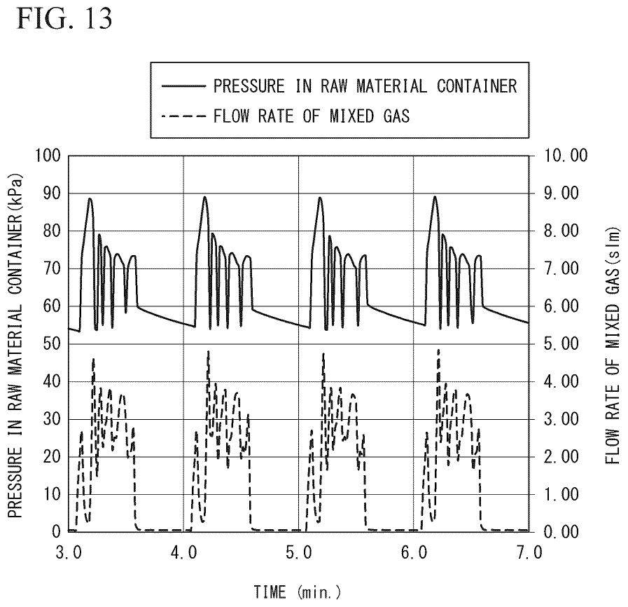

The results are shown in FIG. 13. In FIG. 13, the X-axis represents the supply time (min), the first Y-axis represents the pressure (kPa) inside the container, and the second Y-axis represents the flow rate (sim) of the mixed ga.

As shown in FIG. 13, when the first buffer tank 10 was not provided, it was not possible to stably supply the mixed gas at the set flow rate, even when the flow rate of the mixed gas was controlled by the supply control device 19.

Furthermore, as shown in FIG. 13, it was confirmed that without the first buffer tank 10, sudden pressure fluctuations inside the raw material container 2 could not be suppressed.

### EXPLANATION OF SYMBOLS

1, 21, 31, 41, 51, 61 mixed gas supply device
2, 2A, 2B raw material container
3, 3A, 3B container heater (first beater)
4 container heater-temperature adjusting device (first heater adjusting device)
5 carrier gas-flow rate control device
6 pipe heater (second heater)
7 pipe heater-temperature adjusting device (second heater adjusting device)
8 pressure adjusting device
9 mixed gas-measuring device
9A mixed gas-concentration analysis device
9B mixed gas-flow rate measuring device
10 first buffer tank (buffer tank)
11 first pressure measuring device
12 second pressure measuring device (pressure gauge)
13 detector
14 second buffer tank
15 mixed gas-flow rate control device
16 vacuum pump
17 mixed gas-concentration adjusting device
18 mixed gas-concentration calculation device
19 supply control device
L1, L1A, L1B carrier gas-introduction path
L2, L2A, L2B mixed gas-lead-out path
L3, L3A, L3B bypass path
L4A, L4B exhaust path

1. A mixed gas supply device that supplies a mixed gas containing at least one kind of gas of a film forming material by adjusting the concentration of the film forming material in the mixed gas, comprising:
a raw material container that contains the film forming material;
a first heater that heats the raw material container;
a carrier gas-introduction path that introduces a carrier gas into the raw material container;
a mixed gas-lead-out path that leads the mixed gas out of the raw material container;
a second heater that heats the mixed gas lead-out path;
a pressure adjusting device that is located in the mixed gas lead-out path and that adjusts the pressure in the raw material container;
a mixed gas-measuring device that is located in the mixed gas lead-out path on the primary or secondary side of the pressure adjusting device and that measures the concentration or the flow rate of the mixed gas; and
one or more buffer tanks that are located in the mixed gas lead-out path.

2. The mixed gas supply device according to claim 1,
wherein the buffer tank comprises a first buffer tank that is located on the secondary side of the mixed gas-measuring device.

3. The mixed gas supply device according to claim 1,
wherein the mixed gas supply device further comprises a mixed gas-concentration adjusting device that adjusts a concentration of the film forming material in the mixed gas to a set value, and
wherein the mixed gas-concentration adjusting device has a function of calculating a difference between a measured value of the concentration of the mixed gas obtained by the mixed gas-measuring device and the set value set in the mixed gas-concentration adjusting device, and updating a set pressure value of the pressure adjusting device based on the difference so that the measured value becomes the set value.

4. The mixed gas supply device according to claim 1,
wherein the mixed gas supply device further comprises:
a mixed gas-concentration adjusting device that adjusts the concentration of the film forming material in the mixed gas to a set value;
a carrier gas-flow rate control device that is located in the carrier gas-introduction path; and
a mixed gas-concentration calculation device that calculates a concentration of the film forming material in the mixed gas based on a set value of the flow rate of the carrier gas set in the carrier gas-flow rate control device and a measured value of the flow rate of the mixed gas measured by the mixed gas-measuring device, and
wherein the mixed gas-concentration adjusting device has a function of calculating a difference between a calculated value of the concentration of the mixed gas obtained by the mixed gas-concentration calculation device and the set value set in the mixed gas-concentration adjusting device, and updating a set pressure value of the pressure adjusting device based on the difference so that the calculated value becomes the set value.

5. The mixed gas supply device according to claim 1,
wherein the buffer tank comprises a second buffer tank that is located between the pressure adjusting device and the mixed gas-measuring device.

6. The mixed gas supply device according to claim 1,
wherein the mixed gas supply device further comprises:
a first heater adjusting device that adjusts an output of the first heater;
a mixed gas-concentration adjusting device that adjusts a concentration of the film forming material in the mixed gas to a set value;
a carrier gas-flow rate control device that is located in the carrier gas-introduction path; and
a mixed gas-concentration calculation device that calculates a concentration of the film forming material in the mixed gas based on a set value of the flow rate of the carrier gas set in the carrier gas-flow rate control device and a measured value of a flow rate of the mixed gas measured by the mixed gas-measuring device, and
wherein the mixed gas-concentration adjusting device has a function of calculating a difference between a measured value of a concentration of the mixed gas obtained by the mixed gas-measuring device or a calculated value of a concentration of the mixed gas obtained by the mixed gas-concentration calculation device and the set value set in the mixed gas-concentration adjusting device, and updating a set value of an output of the first heater adjusting device so that the measured value or the calculated value becomes the set value based on the difference.

7. The mixed gas supply device according to claim 2,
wherein the mixed gas supply device further comprises:
a carrier gas-flow rate control device that is located in the carrier gas-introduction path,
a pressure measuring device that measures the pressure in the first buffer tank, and a supply control device that controls the carrier gas-flow rate control device and one or more on-off valves located in the mixed gas lead-out path, and
wherein the supply control device controls the carrier gas-flow rate control device and each of the opening degrees of the one or more on-off valves based on the measurement value of the pressure measuring device.

8. The mixed gas supply device according to claim 2,
wherein the mixed gas supply device further comprises:
a mixed gas-flow rate control device that is located in the mixed gas lead-out path on the secondary side of the first buffer tank.

9. The mixed gas supply device according to claim 7,
wherein the mixed gas supply device further comprises:
a mixed gas-flow rate control device that is located in the mixed gas lead-out path on the secondary side of the first buffer tank.

10. The mixed gas supply device according to any one of claim 1,
wherein the film forming material is one or more compounds selected from the group consisting of a metal containing compound, a nitrogen containing compound, a carbon containing compound, and an oxygen containing compound.

11. The mixed gas supply device according to claim 10,
wherein the nitrogen containing compound is a hydrazine compound.

12. The mixed gas supply device according to claim 1,
wherein the mixed gas supply device further comprises a bypass path that is branched off from the carrier gas-introduction path, bypasses the raw material container and merged with the mixed gas lead-out path.

13. The mixed gas supply device according to claim 1,
wherein the mixed gas supply device further comprises one or more exhaust paths that are branched off from the mixed gas lead-out path, and exhaust the mixed gas in the mixed gas lead-out path.
